(19) United States
(12) Patent Application Publication
(10) Pub. No.: US 2025/0210840 A1
(43) Pub. Date: Jun. 26, 2025

(54) FILTER CIRCUIT AND PLASMA PROCESSING APPARATUS

(71) Applicant: Tokyo Electron Limited, Tokyo (JP)

(72) Inventors: Taro IKEDA, Nirasaki City (JP); Yuki OSADA, Nirasaki City (JP); Shuto WATANABE, Nirasaki City (JP)

(21) Appl. No.: 18/976,723

(22) Filed: Dec. 11, 2024

(30) Foreign Application Priority Data
Dec. 22, 2023 (JP) 2023-216426

(51) Int. Cl. H01P 1/207; H01J 37/32; H01Q 1/12; H01Q 13/06

(52) U.S. Cl. CPC H01P 1/207; H01J 37/3222; H01Q 1/125; H01Q 13/065

(57) ABSTRACT

A filter circuit includes: a housing formed of a conductor and provided with input and output ports that each includes outer and inner conductors, the housing being kept at a ground potential together with the outer conductors of the input and output ports; a protrusion portion formed of a conductor, connected to the housing, and configured to protrude in a spiral shape inside the housing; and a power feeding line provided inside the housing and configured to be insulated from the housing. The power feeding line includes an input-side conductor which is the inner conductor of the input port, an output-side conductor which is the inner conductor of the output port, and an antenna connected to the input-side conductor and the output-side conductor and formed in a spiral shape coaxially with the protrusion portion. The protrusion portion and the antenna form a choke structure.

### CROSS-REFERENCE TO RELATED APPLICATION

This application is based upon and claims the benefit of priority from Japanese Patent Application No. 2023-216426, filed on Dec. 22, 2023, the entire contents of which are incorporated herein by reference.

### TECHNICAL FIELD

The present disclosure relates to a filter circuit and a plasma processing apparatus.

### BACKGROUND

A plasma processing apparatus disclosed in Patent Document 1 is provided with a processing container in which plasma processing is performed, a stage arranged on a plate-shaped conductive base inside the processing container with a space left therebetween and on which a processing target substrate is placed and held, a radio-frequency electrode provided in the stage, a radio-frequency power feeder for applying radio-frequency power having a constant frequency to the radio-frequency electrode, a heating element provided in the stage, a heater power feeding line for electrically connecting the heating element to a heater power supply arranged outside the processing container, and a filter unit including a coil for attenuating or blocking radio-frequency noise entering the heater power feeding line via the heating element and a casing for accommodating the coil.

### PRIOR ART DOCUMENT

### Patent Document

Patent Document 1: Japanese Laid-Open Patent Publication No. 2014-099585

### SUMMARY

According to one embodiment of the present disclosure, a filter circuit includes: a housing formed of a conductor and provided with an input port and an output port that each includes an outer conductor and an inner conductor, the housing being configured to be kept at a ground potential together with the outer conductors of the input port and the output port; a protrusion portion formed of a conductor, connected to the housing, and configured to protrude in a spiral shape inside the housing; and a power feeding line provided inside the housing and configured to be insulated from the housing, wherein the power feeding line is configured to include an input-side conductor which is the inner conductor of the input port, an output-side conductor which is the inner conductor of the output port, and an antenna connected to the input-side conductor and the output-side conductor and formed in a spiral shape coaxially with the protrusion portion, and the protrusion portion and the antenna form a choke structure.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view showing an example of a configuration of a plasma processing apparatus according to an embodiment of the present disclosure.

FIG. 2 is a perspective view showing an example of a filter circuit according to the present embodiment.

FIG. 3 is a cross-sectional view showing an example of a cross section taken along line A-A in FIG. 2.

FIG. 4 is a cross-sectional view showing an example of a cross section taken along line B-B in FIG. 3.

FIG. 5 is a diagram showing an example of a simulation result of an electric field distribution in the filter circuit according to the present embodiment.

FIG. 6 is a graph showing an example of a frequency characteristic of the filter circuit according to the present embodiment.

FIG. 7 is a diagram showing an example of adjustment of a resonant frequency depending on a spiral winding angle.

FIG. 8 is a graph showing an example of a dependency of the spiral winding angle on the resonant frequency.

FIG. 9 is a graph showing an example of a change in the resonant frequency depending on the spiral winding angle.

FIG. 10 is a cross-sectional view showing an example of a filter circuit according to Modification 1.

FIG. 11 is a graph showing an example of a frequency characteristic of the filter circuit according to Modification 1.

### DETAILED DESCRIPTION

Hereinafter, embodiments of a filter circuit and a plasma processing apparatus disclosed herein will be described in detail with reference to the drawings. The technology disclosed herein is not limited by the following embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a plasma processing apparatus, a power supply arranged outside a processing container is connected to an electrostatic chuck and a heater provided on a substrate support for supporting a substrate to be processed. The substrate support constitutes a lower electrode for generating plasma. Therefore, radio frequency waves for plasma generation may affect a power feeding line leading to the electrostatic chuck and the heater. For this reason, a radio-frequency filter including a coil and a capacitor is inserted into the power feeding line. However, the radio-frequency filter including the coil and the capacitor has a complex structure and large dimensions. This makes it difficult to implement a simple and compact radio-frequency filter.

### [Configuration of Plasma Processing System]

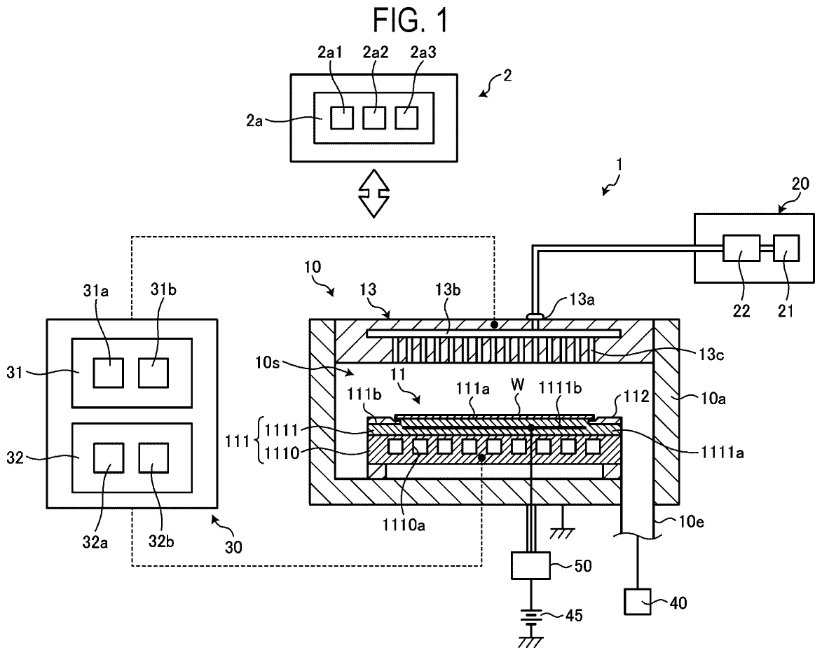

Hereinafter, a configuration example of a plasma processing system will be described. FIG. 1 is a schematic cross-sectional view showing an example of a configuration of a plasma processing apparatus according to an embodiment of the present disclosure. As shown in FIG. 1, the plasma processing system includes a capacitively coupled plasma processing apparatus 1 and a controller 2. The capacitively coupled plasma processing apparatus 1 includes a plasma processing chamber 10, a gas supplier 20, a power supply 30, an evacuation system 40, a DC power supply 45, and a filter circuit 50. The plasma processing apparatus 1 also includes a substrate support 11 and a gas introducer. The gas introducer is configured to introduce at least one processing gas into the plasma processing chamber 10. The gas introducer includes a shower head 13. The substrate support 11 is disposed inside the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port through which at least one processing gas is supplied to the plasma processing space 10s and at least one gas exhaust port through which a gas is exhausted from the plasma processing space 10s. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Therefore, the central region 111a may be referred to as a substrate support surface for supporting the substrate W, and the annular region 111b may be referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed inside the ceramic member 1111a. The ceramic member 1111a has a central region 111a. In one embodiment, the ceramic member 1111a also has an annular region 111b. Other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. The electrostatic electrode 1111b is connected to the DC power supply 45 via the filter circuit 50. When a voltage is applied to the electrostatic electrode 1111b from the DC power supply 45, an electrostatic attraction force is generated between the electrostatic chuck 1111 and the substrate W. The substrate W is attracted to the electrostatic chuck 1111 by the generated electrostatic attraction force and is held by the electrostatic chuck 1111.

In addition, at least one RF (radio frequency)/DC electrode coupled to an RF power supply 31 and/or a direct current (DC) power supply 32, which will be described later, may be disposed inside the ceramic member 1111a. In this case, the at least one RF/DC electrode functions as a lower electrode. In a case in which a bias RF signal and/or a DC signal, which will be described later, is supplied to the at least one RF/DC electrode, the RF/DC electrode may be referred to as a bias electrode. The conductive member of the base 1110 and the at least one RF/DC electrode may function as a plurality of lower electrodes. Further, the electrostatic electrode 1111b may function as a lower electrode. Thus, the substrate support 11 includes at least one lower electrode.

The substrate support 11 may also include a temperature adjustment module configured to adjust a temperature of at least one of the electrostatic chuck 1111, the ring assembly 112, and the substrate W to a target temperature. The temperature adjustment module may include a heater, a heat transfer medium, a flow path 1110a, or a combination thereof. A heat transfer fluid such as a brine or a gas flows through the flow path 1110a. In one embodiment, the flow path 1110a is formed inside the base 1110, and one or more heaters are disposed inside the ceramic member 1111a of the electrostatic chuck 1111. The substrate support 11 may also include a heat transfer gas supplier configured to supply a heat transfer gas to a gap between a back surface of the substrate W and the central region 111a.

The shower head 13 is configured to introduce at least one processing gas from the gas supplier 20 into the plasma processing space 10s. The shower head 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. The shower head 13 also includes at least one upper electrode. In addition to the shower head 13, the gas introducer may include one or more side gas injectors (SGIs) attached to one or more openings formed in the sidewall 10a.

The gas supplier 20 may include at least one gas source 21 and at least one flow rate controller 22. In one embodiment, the gas supplier 20 is configured to supply at least one processing gas from the corresponding gas source 21 through the corresponding flow rate controller 22 to the shower head 13. Each flow rate controller 22 may include, for example, a mass flow controller or a pressure-controlled flow rate controller. Further, the gas supplier 20 may include one or more flow modulation devices for modulating or pulsing a flow rate of the at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. As a result, plasma is formed from at least one processing gas supplied to the plasma processing space 10s. Thus, the RF power supply 31 may function as at least a part of a plasma generator configured to generate plasma from one or more processing gases in the plasma processing chamber 10. In addition, a bias potential is generated on the substrate W by supplying a bias RF signal to the at least one lower electrode. Ion components in the formed plasma may be drawn into the substrate W.

In one embodiment, the RF power supply 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency in a range of 10 MHz to 300 MHz. In one embodiment, the first RF generator 31a may be configured to generate a plurality of source RF signals having different frequencies. The one or more source RF signals thus generated are supplied to at least one lower electrode and/or at least one upper electrode.

The second RF generator 31b is coupled to the at least one lower electrode via at least one impedance matching circuit and is configured to generate a bias RF signal (bias RF power). A frequency of the bias RF signal may be the same as or different from the frequency of the source RF signal. In one embodiment, the bias RF signal has a lower frequency than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. The one or more bias RF signals thus generated are supplied to the at least one lower electrode. Further, in various embodiments, at least one of the source RF signal and the bias RF signal may be pulsed.

Further, the power supply 30 may include a DC power supply 32 coupled to the plasma processing chamber 10. The DC power supply 32 includes a first DC generator 32a and a second DC generator 32b. In one embodiment, the first DC generator 32a is connected to at least one lower electrode and configured to generate a first DC signal. The first DC signal (bias DC signal) thus generated is applied to the at least one lower electrode. In one embodiment, the second DC generator 32b is connected to at least one upper electrode and is configured to generate a second DC signal. The second DC signal thus generated is applied to the at least one upper electrode.

In various embodiments, at least one of the first and second DC signals may be pulsed. In this case, a sequence of voltage pulses is applied to at least one lower electrode and/or at least one upper electrode. The voltage pulses may have a rectangular pulse waveform, a trapezoidal pulse waveform, a triangular pulse waveform, or a combination of these pulse waveforms. In one embodiment, a waveform generator for generating the sequence of voltage pulses from the DC signal is connected between the first DC generator 32a and at least one lower electrode. Thus, the first DC generator 32a and the waveform generator constitute a voltage pulse generator. In a case in which the second DC generator 32b and the waveform generator constitute the voltage pulse generator, the voltage pulse generator is connected to at least one upper electrode. The voltage pulses may have a positive polarity or a negative polarity. Further, the sequence of voltage pulses may include one or more positive polarity voltage pulses and one or more negative polarity voltage pulses within one period. The first DC generator 32a and the second DC generator 32b may be provided in addition to the RF power supply 31, or the first DC generator 32a may be provided in place of the second RF generator 31b.

The evacuation system 40 may be connected to, for example, a gas exhaust port 10e provided at the bottom of the plasma processing chamber 10. The evacuation system 40 may include a pressure regulation valve and a vacuum pump. An internal pressure of the plasma processing space 10s is adjusted by the pressure regulation valve. The vacuum pump may include a turbo-molecular pump, a dry pump, or a combination thereof.

When plasma is generated in the plasma processing space 10s, the filter circuit 50 removes the influence of radio-frequency power for plasma generation or radio-frequency power for bias on the DC power supply 45. The filter circuit 50 passes a DC applied from the DC power supply 45 to the electrostatic electrode 1111b therethrough and cut offs radio-frequency power flowing backward from the electrostatic electrode 1111b.

The controller 2 processes computer-executable instructions that cause the plasma processing apparatus 1 to execute various processes described in the present disclosure. The controller 2 may be configured to control each element of the plasma processing apparatus 1 to execute various processes described herein. In one embodiment, a part or the entirety of the controller 2 may be included in the plasma processing apparatus 1. The controller 2 may include a processor 2a1, a memory 2a2, and a communication interface 2a3. The controller 2 is implemented by, for example, a computer 2a. The processor 2al may be configured to perform various control operations by reading a program from the memory 2a2 and executing the read program. This program may be stored in the memory 2a2 in advance, or may be acquired via a medium when necessary. The acquired program is stored in the memory 2a2. The program is read from the memory 2a2 and executed by the processor 2a1. The medium may be various storage media readable by the computer 2a, or may be a communication line connected to the communication interface 2a3. The processor 2al may be a CPU (Central Processing Unit). The memory 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### [Structure of Filter Circuit 50]

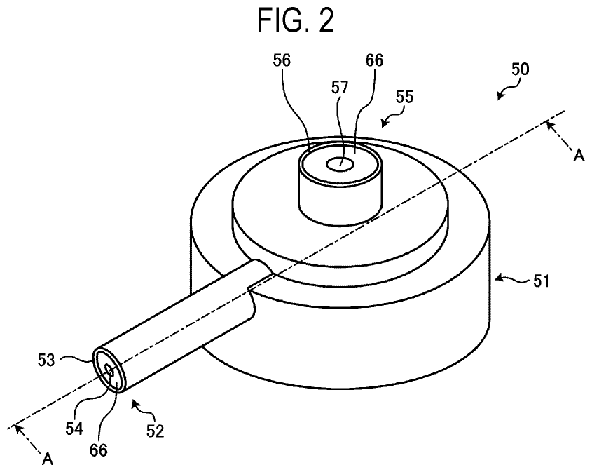

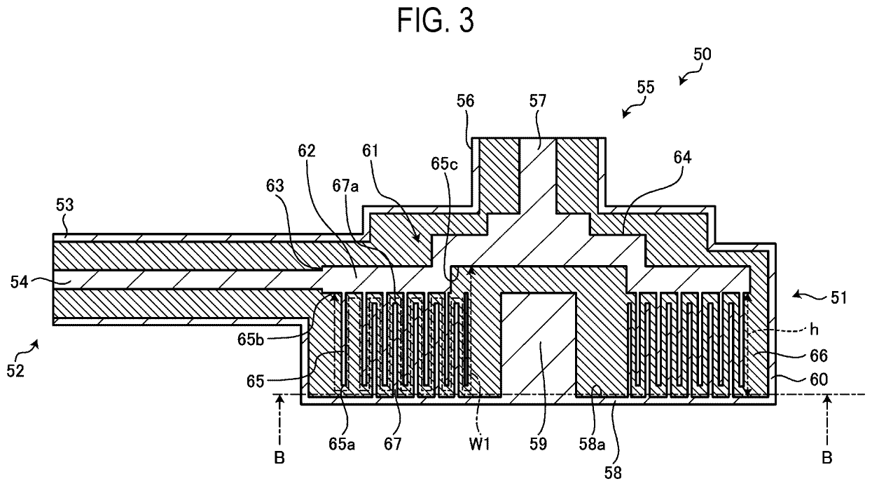

Next, details of the filter circuit 50 will be described with reference to FIGS. 2 to 4. FIG. 2 is a perspective view showing an example of the filter circuit according to the present embodiment. FIG. 3 is a cross-sectional view showing an example of a cross section taken along A-A line in FIG. 2. As shown in FIGS. 2 and 3, the filter circuit 50 includes a housing 51. The housing 51 is made of a conductor such as aluminum or copper. The housing 51 also includes an input port 52 and an output port 55. In the present embodiment, the radio-frequency power is cut off. Thus, based on a flow direction of the radio-frequency power, a side of the housing 51 connected to the electrostatic electrode 1111b is referred to as the input port 52, and a side of the housing 51 connected to the DC power supply 45 is referred to as the output port 55. The connection destinations of the input port 52 and the output port 55 may be interchanged.

The input port 52 and the output port 55 are formed by outer conductors 53 and 56 and inner conductors 54 and 57, respectively. That is, the input port 52 and the output port 55 have a coaxial structure. The housing 51 is electrically connected to the outer conductors 53 and 56, and is kept at a ground potential together with the grounded plasma processing chamber 10 via a coaxial cable connected to the input port 52, a frame on which the filter circuit 50 is installed, or the like. The housing 51 has a shape of a cylinder. The input port 52 is formed on a side surface 60 of the cylinder. The housing 51 may have a square cylindrical cross section. The output port 55 of the housing 51 is formed on a side of one end of the cylinder on which the input port 52 is formed, and the other end 58 is formed in a disk shape so as to close the cylinder. Further, a central protrusion 59 formed of a conductor such as aluminum or copper and provided to protrude into the housing 51, and a fin 67 formed in a spiral shape approximately about the central protrusion 59 as a center are connected to the end 58. The central protrusion 59 has, for example, a circular columnar shape. The fin 67 is an example of the protrusion portion and an example of a first fin connected to the base (end 58) of the protrusion portion.

An antenna 65 formed in a spiral shape coaxially with the fin 67 is provided inside the housing 51 approximately about the central protrusion 59 as a center. The antenna 65 is formed of a conductor such as aluminum or copper, and a spiral fin formed on the base 62 of the antenna 65 is formed so as to alternately intertwine with the fin 67 in the A-A cross section. That is, the antenna 65 is equivalent to a cylindrical multipole antenna when viewed from the electromagnetic wave of a frequency to be cut off. In other words, the antenna 65 is an antenna (coaxial insertion multipole antenna) that does not radiate an electromagnetic wave of a frequency to be cut off. If the tip 65a of the antenna 65 and the tip 67a of the fin 67 are excessively pointed, the electric field will concentrate. Therefore, it is preferable that the antenna 65 and the fin 67 have a certain degree of thickness. In addition, the narrower the gap between the antenna 65 and the fin 67, the better the frequency characteristic described below. The antenna 65 is an example of a second fin.

The base 62 has a disc shape, and the central portion thereof is convex so as to be offset toward the output port 55. The inner conductor 54 is connected to a side surface 63 of the base 62. The inner conductor 57 is connected to an upper surface 64 of the base 62. That is, the inner conductor (input-side conductor) 54 of the input port 52, the inner conductor (output-side conductor) 57 of the output port 55, and the antenna 65 including the base 62 constitute a power feeding line 61 insulated from the housing 51. That is, in the filter circuit 50, the power feeding line 61 formed by the inner conductor 54, the antenna 65, and the inner conductor 57 is arranged at a right angle. The power feeding line 61 is a path for supplying a direct current from the DC power supply 45 to the electrostatic electrode 1111b. In addition, the connection portion of the upper surface 64 connected to the inner conductor 57 may be further convex as shown in FIG. 3.

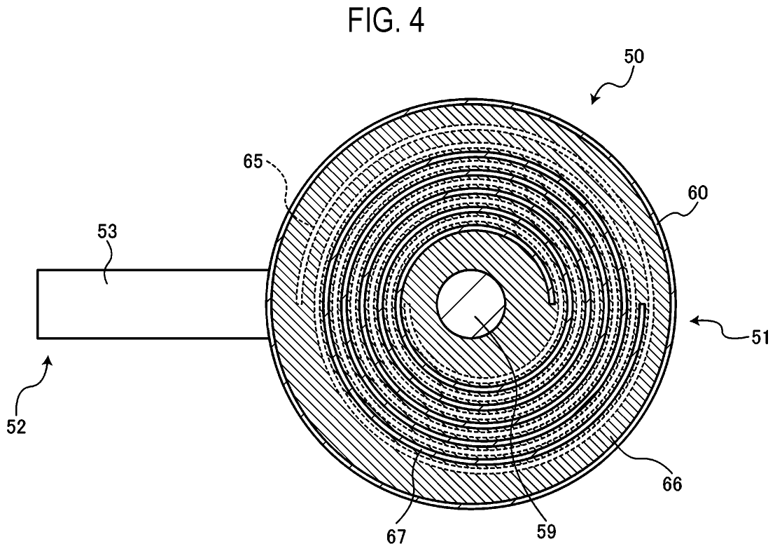

FIG. 4 is a cross-sectional view showing an example of a cross section taken along line B-B in FIG. 3. As shown in FIG. 4, in the filter circuit 50, the antenna 65 and the fin 67 are formed in a coaxial spiral shape inside the housing 51 approximately about the central protrusion 59 as a center. That is, the antenna 65 and the fin 67 are formed in a coaxial helical shape in the B-B cross section. In FIG. 4, the antenna 65 is represented by a broken line, assuming that a dielectric 66 (to be described later) exists between the tip 65a of the antenna 65 and the fin 67 in the B-B cross section. In the example of FIG. 4, the antenna 65 has a spiral shape with six turns, and the fin 67 has a spiral shape with five turns. The number of turns of the spiral shape is not limited thereto. In addition, the antenna 65 and the fin 67 may be made smaller as the number of turns of the spiral shape increases, provided that they have the same resonant frequency. For example, the antenna 65 and the fin 67 are arranged such that the inner and outer ends of the spiral shape are shifted by 180 degrees from each other. The angle of shift of the respective ends on the inner circumference side is related to the resonant frequency of a harmonic, which will be described later, and is changed depending on the resonant frequency of the harmonic. In addition, the position of the end of the antenna 65 on the outer circumference side does not have to be aligned with the input port 52.

The dielectric 66 is provided between the housing 51 and the power feeding line 61. That is, the dielectric 66 is filled between the central protrusion 59 and the antenna 65 and the fin 67, between the antenna 65 and the fin 67, between the antenna 65 and the fin 67 and the side surface 60 of the cylinder, and between the tip 65a of the antenna 65 and the end 58. Since the space between the antenna 65 and the fin 67 is spiral, a sheet-like dielectric 66 may be sandwiched between the antenna 65 and the fin 67 to easily form a state in which the space is filled with the dielectric 66. Similarly, the dielectric 66 is filled between the outer conductor 53 and the inner conductor 54 of the input port 52, and between the outer conductor 56 and the inner conductor 57 of the output port 55. As the dielectric 66, for example, PTFE (polytetrafluoroethylene) or the like may be used. In the A-A cross section shown in FIG. 3, a portion of the antenna 65 located near central protrusion 59 appears to be floating inside dielectric 66. However, the antenna 65 is actually connected to base 62. In addition, the fin 67 is not floating but is connected to the end 58.

Further, in the antenna 65, the space between the antenna 65 and the housing 51, the fin 67 and the central protrusion 59, which extends from the outer circumference surface 65b of the base 62 of the antenna 65 to the central surface 65c, forms a choke structure based on a length of a quarter wavelength of the electromagnetic wave to be cut off. In the A-A cross section shown in FIG. 3, the path from the surface 65b to the surface 65c, which is folded multiple times between the antenna 65 and the fin 67 via the inner surface 58a facing the tip 65a is a transmission path length W1. In other words, the transmission path length W1 forms a choke structure, that is, a so-called λ/4 choke based on the length of a quarter wavelength of the electromagnetic wave to be cut off. That is, since the electromagnetic wave to be cut off travels back and forth along the transmission path length W1, the antenna 65 becomes a half-wavelength antenna that is twice the transmission path length W1. It may be considered that the electromagnetic wave is radiated from the entire ring-shaped surface 65b. In FIG. 3, there are portions between the spirals of the antenna 65 where there is no fin 67. However, for the sake of convenience in description, the transmission path length W1 is indicated as if there were the fin 67. In the case in which the portions between the spirals of the antenna 65 where there is no fin 67 occupy most of the circumferential direction, it may be considered that the paths connecting the tips 65a of the antenna 65 in those portions are included in the transmission path length W1.

In this regard, the height h of the antenna 65 and the fin 67 is required to be sufficiently shorter than the cutoff wavelength λc in order to function as an electromagnetic wave choke. Since the electromagnetic wave mode that may propagate through the antenna 65 and the fin 67 is a TE01 mode, the cutoff wavelength λc is given by the following formula (1). Further, when the effective wavelength of the electromagnetic wave inputted to the filter circuit 50 is Ain, the condition for the electromagnetic wave choke to function is given by the following formula (2).

$$λ c = 2 h \qquad ( 1 )$$

$$λ in ≫ λ c \qquad ( 2 )$$

For example, a case is considered in which the frequency of the radio-frequency power, which is the electromagnetic wave to be cut off, that is, the input electromagnetic wave, is 220 MHz, and PTFE having a relative dielectric constant of 2.1 is used for the dielectric 66. In this case, the effective wavelength in the dielectric 66 is λin=941 mm. For example, in the filter circuit 50, when the height h is 6 mm, the cutoff wavelength λc is 32 mm. It may be seen that the above formula (2) is established and the electromagnetic wave choke functions. The path along the spiral may also be regarded as a waveguide. However, the electromagnetic wave is cut off and is not transmitted through the path along the spiral. Further, as long as the electromagnetic wave choke functions, the number of antenna 65 and fin 67 is not limited, and the fin on the antenna 65 side and the fin on the end 58 side (fin 67 side) may each be composed of multiple fins.

### [Simulation Result]

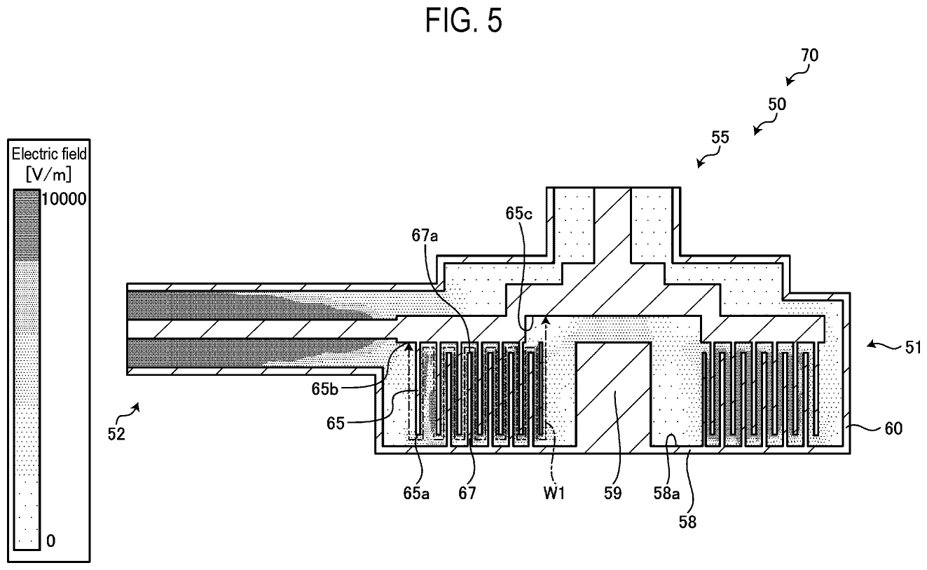

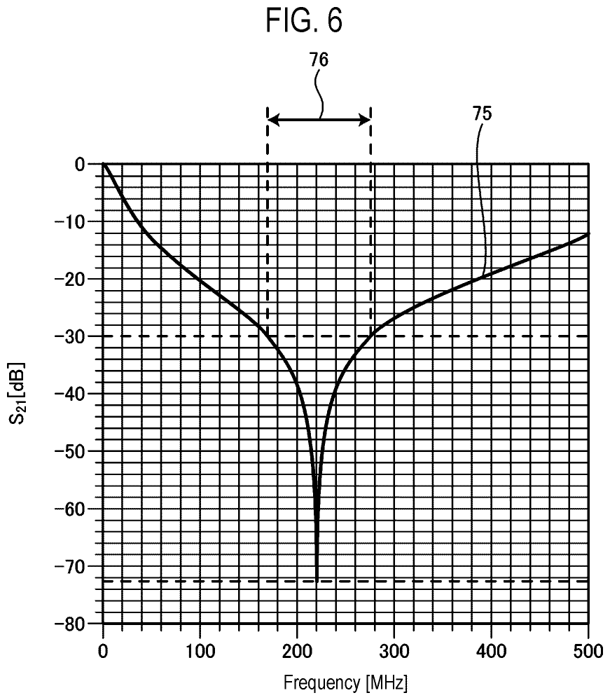

Next, a simulation result of an electric field distribution in the filter circuit 50 will be described with reference to FIGS. 5 and 6. FIG. 5 is a diagram showing an example of the simulation result of the electric field distribution in the filter circuit according to the present embodiment. The simulation result 70 shown in FIG. 5 shows the electric field distribution when a radio-frequency power of 220 MHz and 1,000 W is inputted from the input port 52. In the simulation result 70, the electric field intensity is high in the space between the antenna 65 and the fin 67 in the transmission path length W1 extending from the surface 65b to the surface 65c. Further, the electric field intensity is relatively lower in the space between the antenna 65 and the fin 67 and the side surface 60, and in the space between the antenna 65 and the fin 67 and the central protrusion 59 than in the space between the antenna 65 and the fin 67. Further, the electric field intensity is almost zero in the vicinity of the output port 55. That is, the antenna 65 and fin 67 inside the housing 51 generate a reflected wave shifted by 180 degrees in phase from a traveling wave. The traveling wave and the reflected wave cancel each other out, so that the output of the radio-frequency power of 220 MHz from the output port 55 becomes 0 W. Although a portion of the antenna 65 located near the central protrusion 59 appears to be floating in the cross section of FIG. 5 (corresponding to the A-A cross section in FIG. 3), the antenna 65 is actually connected to the base 62. The fin 67 is also not floating but is connected to the end 58.

FIG. 6 is a graph showing an example of a frequency characteristic of the filter circuit according to the present embodiment. The graph 75 shown in FIG. 6 represents the frequency characteristic of the filter circuit 50 in terms of S-parameter S₂₁. In FIG. 6, the vertical axis of the graph represents S₂₁ (insertion loss). The attenuation amount increases toward the negative side. As shown in the graph 75, the attenuation amount of the filter circuit 50 is maximum at 220 MHz, and the insertion loss is −72 dB. Further, the insertion loss in a range 76 of 170 MHZ to 270 MHz is −30 dB or less. That is, the filter circuit 50 forms a band-stop filter having a center frequency of 220 MHz. Thus, in the present embodiment, a three-dimensional circuit using a multipole antenna with a spiral fin resonates the radio-frequency wave having a frequency to be cut off. Therefore, for example, a simple and compact radio-frequency filter for high-output radio-frequency power such as 1,000 W in a VHF (Very High Frequency) band may be implemented. In addition, since the power feeding line 61 is insulated from the housing 51, the output of the DC power supply 45 may be applied to the electrostatic electrode 1111b without causing a ground fault. Further, according to the present embodiment, in the frequency range shown in the range 76, it is possible to cut off the electromagnetic wave (single peak waveform) whose frequency is variable using FM modulation or the like, and the electromagnetic wave (broadband waveform) of multiple frequencies generated in multiple tones.

### [Adjustment of the Number of Turns of Spiral]

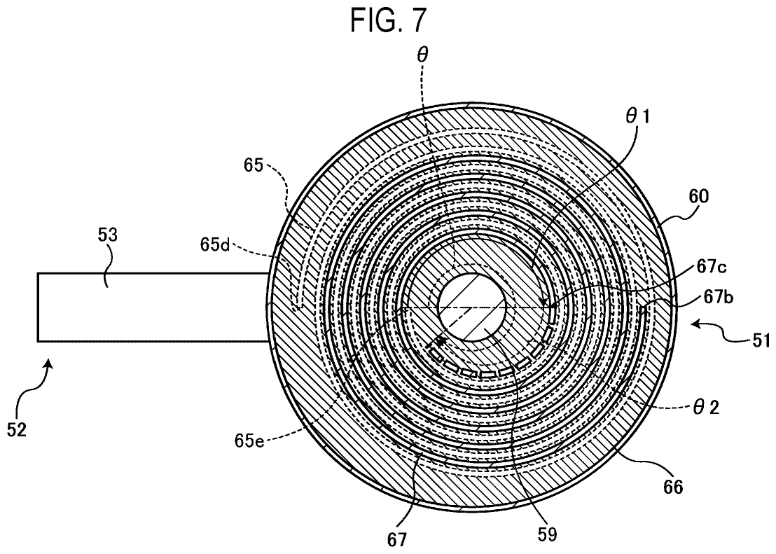

Next, an adjustment of the resonant frequency by the number of turns of the spiral of the antenna 65 and the fin 67 will be described with reference to FIGS. 7 to 9. FIG. 7 is a diagram showing an example of the adjustment of the resonant frequency by a spiral winding angle. As shown in FIG. 7, the antenna 65 has six turns of the spiral from the outer end 65d to the inner end 65e of the spiral. The fin 67 has five turns of the spiral from the outer end 67b to the inner end 67c of the spiral. The fin 67 may have six turns of the spiral, just like the antenna 65. In this case, the resonant frequency may be set to 220 MHz by adjusting the dimensions of each part of the filter circuit 50.

Now, attention is paid to an angular shift in the circumferential direction approximately about the central protrusion 59 as a center between the end 65e on the inner circumference side of the antenna 65 and the end 67c on the inner circumference side of the fin 67. For example, in FIG. 7, the line connecting the central protrusion 59 and the end 65e is set to 0 degrees as a reference, and the angle θ of the end 67c is changed in a clockwise direction. The position where the angle θ of the end 67c is 180 degrees is set to an initial angle θ1. The angle θ is also expressed as the spiral winding angle. In the filter circuit 50, the resonant frequency (fundamental frequency) of the filter circuit 50 and the resonant frequency of the harmonic are changed by changing the angle θ of the end 67c. That is, in the filter circuit 50, the resonant frequency (fundamental frequency) and the resonant frequency of the harmonic are determined by a difference in the circumferential length between the end 65e and the end 67c. Changing the angle θ of the end 67c may be said to adjust the number of turns of one of the antenna 65 and the fin 67 so that the number of turns of the antenna 65 and the number of turns of the fin 67 are different. That is, the number of turns includes a decimal value corresponding to the angle θ. The angle θ of the end 67c is structurally changed. When positions of the end 65d and the end 67b on the outer circumference side are changed to match the end 65e and the end 67c on the inner circumference side, the resonance frequency of the filter circuit 50 as a reference will also be shifted. Therefore, it is preferable to fix the positions of the end 65d and the end 67b on the outer circumference side.

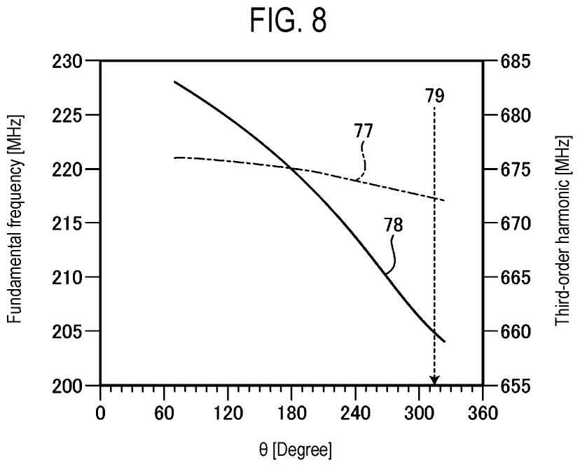

FIG. 8 is a graph showing an example of a dependency of the spiral winding angle on the resonant frequency. As shown in FIG. 8, the graph 77 shows a relationship between the fundamental frequency of the filter circuit 50 and the angle θ. The graph 78 shows a relationship between the resonant frequency of the filter circuit 50 at a frequency near a third-order harmonic and the angle θ. When the angle θ is the initial angle θ1 (180 degrees), in the graphs 77 and 78, the fundamental frequency is 220 MHz and the resonant frequency near the third-order harmonic is 675 MHz. When the angle θ of the end 67c is changed in a clockwise direction by adding an angle θ2 to the angle θ1, at the position 79 where the angle θ is 315 degrees, the fundamental frequency is 217 MHz and the resonant frequency near the third-order harmonic is 660 MHz.

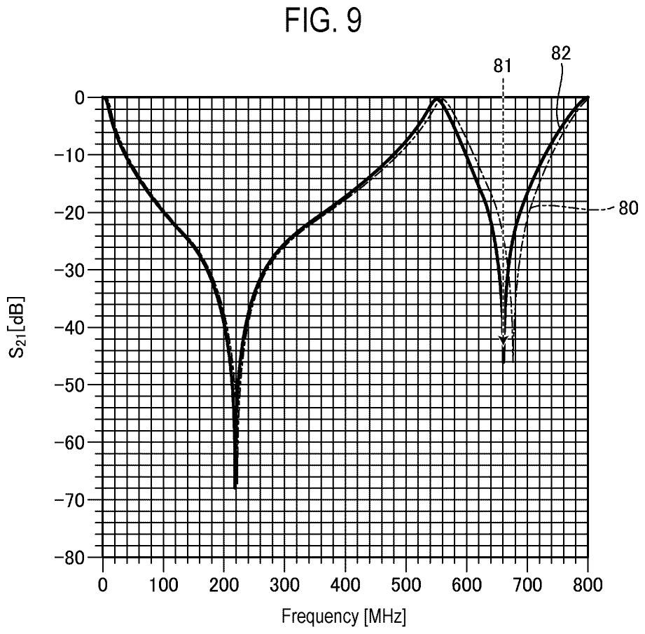

FIG. 9 is a graph showing an example of a change in resonant frequency due to the spiral winding angle. The graphs 80 and 82 shown in FIG. 9 respectively indicate the frequency characteristics of the filter circuit 50 at the angle θ1 (180 degrees) and the adjusted angle θ (315 degrees) in terms of the S-parameter S₂₁. FIG. 9 also shows the third-order harmonic (660 MHz) having the fundamental frequency (220 MHz) of the electromagnetic wave to be cut off as a third-order harmonic 81. In the graph 80, the insertion loss of the filter circuit 50 is −67 dB at 220 MHz, −23 dB at 660 MHz, and −46 dB at 675 MHz. In this case, the insertion loss is not −30 dB or less at the third-order harmonic 81 (660 MHz) of the electromagnetic wave to be blocked, and the attenuation amount is insufficient. On the other hand, in the graph 82, the insertion loss of the filter circuit 50 is −68 dB at 220 MHz and −46 dB at 660 MHz. In this case, the insertion loss is −30 dB or less at the third-order harmonic 81 (660 MHZ) of the electromagnetic wave to be cut off, and the amount of attenuation is sufficiently obtained. That is, in the filter circuit 50, by adjusting the angle θ of the end 67c from 180 degrees to 315 degrees, it is possible to simultaneously attenuate and cut off both the fundamental frequency (220 MHz) and the third-order harmonic (660 MHz) of the electromagnetic wave to be cut off. In the same way, the filter circuit 50 may also attenuate and cut off an Nth-order harmonic, which is an odd multiple.

### [Modification]

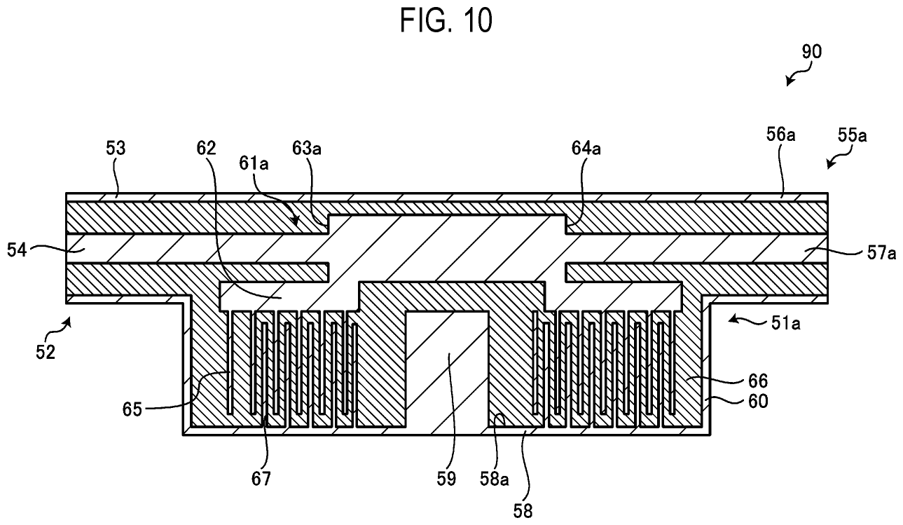

Next, Modification 1 in which the position of the output port 55 is changed will be described. FIG. 10 is a cross-sectional view showing an example of a filter circuit according to Modification 1. In the filter circuit 90 shown in FIG. 10, the position of the output port 55a is set to the side surface 60 of the cylinder of the housing 51a opposite to the input port 52. In the filter circuit 90, the same components as those in the filter circuit 50 are designated by the same reference numerals, and redundant descriptions of the components and operations will be omitted. The output port 55a is formed by an outer conductor 56a and an inner conductor 57a. In the housing 51a, the end of the cylinder on a side where the input port 52 and the output port 55a are formed is closed. The end of the cylinder corresponds to a surface on which the output port 55 is formed in FIG. 2. The outer conductor 56a is electrically connected to the housing 51a. The inner conductor 57a is connected to the side surface 64a of the base 62. The side surface 64a is located opposite to the side surface 63a where the inner conductor 54 of the input port 52 is connected to the base 62. That is, in the filter circuit 90, the power feeding line 61a formed by the inner conductor 54, the antenna 65, and the inner conductor 57a is arranged in a straight line. Although a portion of the antenna 65 located near the central protrusion 59 appears to be floating in the dielectric 66 in the cross section of FIG. 10, the antenna 65 is actually connected to the base 62. Likewise, the fin 67 is not floating but is connected to the end 58.

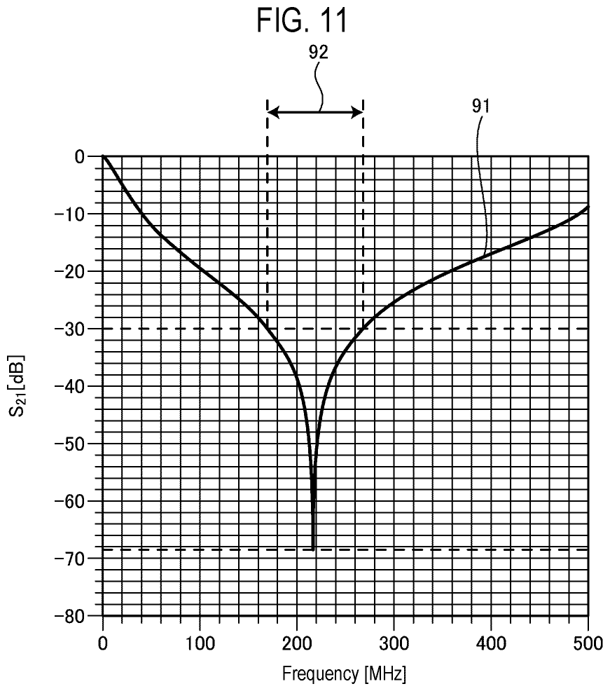

FIG. 11 is a graph showing an example of a frequency characteristic of the filter circuit according to Modification 1. The graph 91 shown in FIG. 11 represents the frequency characteristic of the filter circuit 90 in terms of the S-parameter S₂₁. In FIG. 11, the vertical axis of the graph represents S₂₁ (insertion loss) as in FIG. 6. The attenuation amount increases toward the negative side. As shown in the graph 91, the attenuation amount in the filter circuit 90 is maximum at 220 MHz, and the insertion loss is-68 dB. Further, the insertion loss in a range 92 of 170 MHz to 270 MHz is −30 dB or less. Thus, in Modification 1, the three-dimensional circuit using the multipole antenna with the spiral fin resonates the radio frequency of the frequency to be cut off. Therefore, a simple and compact radio-frequency filter for high-output radio-frequency power such as 1,000 W in the VHF band may be implemented. Further, since the power feeding line 61a is insulated from the housing 51a, the output of the DC power supply 45 may be applied to the electrostatic electrode 1111b without causing a ground fault.

In the above-described embodiment, the case where the central protrusion 59 and the fin 67 are fixed has been described. However, the present disclosure is not limited thereto. For example, the fin 67 may be formed so as to be insertable into and removable from the antenna 65. In this case, the fin 67 is driven by a drive mechanism (not shown) to change the height h. As the drive mechanism, a combination of a stepping motor and a lead screw may be used. By inserting or removing the fin 67 to change the height h, it is possible to change the frequency cut off by the filter circuit 50.

As described above, according to the present embodiment, the filter circuit 50 or 90 includes the housing 51 or 51a, the protrusion portion (the fin 67), and the power feeding line 61 or 61a. The housing 51 or 51a is formed of a conductor, and includes the input port 52 and the output port 55 formed of the outer conductors 53 or 56 and the inner conductors 54 or 57. The housing 51 or 51a is configured to be kept at a ground potential together with the outer conductors 53 or 56 of the input port 52 and the output port 55. The protrusion portion is formed of a conductor, is connected to the housing 51 or 51a, and is configured to protrude in a spiral shape into the housing 51 or 51a. The power feeding line 61 or 61a is provided inside the housing 51 or 51a, and is insulated from the housing 51 or 51a. The power feeding line 61 or 61a is configured to include an input-side conductor, which is the inner conductor 54 of the input port 52, an output-side conductor, which is the inner conductor 57 of the output port 55, and an antenna 65 connected to the input-side conductor and the output-side conductor and formed in a spiral shape coaxially with the protrusion portion. The protrusion portion and the antenna 65 form a choke structure. As a result, a simple and compact radio-frequency filter may be implemented.

Further, according to the present embodiment, the filter circuit 50 or 90 is configured to further include the dielectric 66 between the housings 51 or 51a and the power feeding lines 61 or 61a. As a result, the filter circuit 50 or 90 may be made smaller in size.

Further, according to the present embodiment, the input port 52 and the output port 55 have a coaxial structure, so that a filter circuit for high-output radio-frequency power may be formed.

According to the present embodiment, the choke structure is constituted with the plurality of fins. The plurality of fins includes the first fin (fin 67) connected to the base (end 58) of the protrusion portion and the second fin connected to the base 62 of the antenna 65. The first fin and the second fin are arranged in an alternate manner. As a result, the choke structure may be easily formed.

According to the present embodiment, the plurality of fins includes two fins such as the first fin and the second fin which are formed in a spiral shape. As a result, the choke structure may be easily formed.

Further, according to the present embodiment, the space between the housings 51 or 51a and the protrusion portion and the antenna 65, which extends from the outer circumferential surface 65b of the base 62 of the antenna 65 to the central surface 65c, forms a choke structure based on a quarter wavelength of the electromagnetic wave to be cut off. As a result, it is possible to cut off the radio-frequency power having a frequency to be cut off.

Further, according to the present embodiment, the number of turns of the spiral of the protrusion portion and the antenna 65 is adjusted based on the wavelength of the electromagnetic wave to be cut off. As a result, it is possible to cut off the radio-frequency power having a frequency to be cut off.

Further, according to the present embodiment, the number of turns of one of the protrusion portion and the antenna 65 is adjusted so that the number of turns of the protrusion portion and the number of turns of the antenna 65 are different from each other. As a result, it is possible to cut off the radio-frequency power having a frequency to be cut off and an odd multiple harmonic.

Moreover, according to the present embodiment, there is further provided the drive mechanism capable of adjusting the distance between the base of the protrusion portion and the base 62 of the antenna 65. As a result, it is possible to change the frequency cut off by the filter circuit 50 or 90.

The embodiments disclosed herein should be considered to be exemplary and not limitative in all respects. The above-described embodiments may be omitted, substituted, or modified in various forms without departing from the scope and spirit of the appended claims.

In the above-described embodiments, the transmission path length W1 is set to a quarter wavelength of the electromagnetic wave to be cut off. However, the present disclosure is not limited thereto. For example, the dimensions and number of turns of the antenna 65 and the fin 67 may be set to provide a transmission path length at which the traveling wave and the reflected wave cancel each other out.

In the above-described embodiments, the filter circuit 50 or 90 is connected to the electrostatic electrode 1111b inside the electrostatic chuck 1111. However, the present disclosure is not limited thereto. For example, the filter circuit 50 or 90 may be connected to a heater (not shown) provided inside the substrate support 11.

In the above-described embodiment, the plasma processing apparatus 1 which performs a process such as etching on the substrate W using the capacitively coupled plasma as a plasma source has been described as an example. However, the technology disclosed herein is not limited thereto. As long as the apparatus is one that performs the process on the substrate W using plasma, the plasma source is not limited to the capacitively coupled plasma, and may be any plasma source such as inductively coupled plasma, microwave plasma, or magnetron plasma.

According to the present disclosure in some embodiments, it is possible to implement a simple and compact radio-frequency filter.

Further, the present disclosure may have the following configurations.
(1) A filter circuit includes: a housing formed of a conductor and provided with an input port and an output port that each includes an outer conductor and an inner conductor, the housing being configured to be kept at a ground potential together with the outer conductors of the input port and the output port; a protrusion portion formed of a conductor, connected to the housing, and configured to protrude in a spiral shape inside the housing; and a power feeding line provided inside the housing and configured to be insulated from the housing, wherein the power feeding line is configured to include an input-side conductor which is the inner conductor of the input port, an output-side conductor which is the inner conductor of the output port, and an antenna connected to the input-side conductor and the output-side conductor and formed in a spiral shape coaxially with the protrusion portion, and the protrusion portion and the antenna form a choke structure.
(2) The filter circuit of (1) above further includes: a dielectric provided between the housing and the power feeding line.
(3) In the filter circuit of (1) or (2) above, the input port and the output port have a coaxial structure.
(4) In the filter circuit of any one of (1) to (3) above, the choke structure includes a plurality of fins, and the plurality of fins includes a first fin connected to a base of the protrusion portion and a second fin connected to a base of the antenna, which are arranged in an alternate manner.
(5) In the filter circuit of (4) above, the first fin and the second fin of the plurality of fins are formed in a spiral shape.
(6) In the filter circuit of any one of (1) to (5) above, a space between the housing and the protrusion portion and the antenna, which extends from an outer circumferential surface of a base of the antenna to a central surface of the base, forms the choke structure based on a quarter wavelength of an electromagnetic wave to be cut off.
(7) In the filter circuit of any one of (1) to (6) above, the protrusion portion and the antenna are configured to adjust the number of turns of the spiral based on a wavelength of an electromagnetic wave to be cut off.
(8) In the filter circuit of (7) above, the number of turns of one of the protrusion portion and the antenna is adjusted so that the number of turns of the protrusion portion and the number of turns of the antenna are different from each other.
(9) The filter circuit of any one of (1) to (8) above further includes a drive mechanism configured to adjust a distance between a base of the protrusion portion and a base of the antenna.
(10) A plasma processing apparatus includes: a processing container; an electrode provided inside the processing container, wherein two or more frequencies are applied to the electrode; and a filter circuit. The filter circuit includes: a housing formed of a conductor and provided with an input port and an output port that each includes an outer conductor and an inner conductor, the housing being configured to be kept at a ground potential together with the outer conductors of the input port and the output port; a protrusion portion formed of a conductor, connected to the housing, and configured to protrude in a spiral shape inside the housing; and a power feeding line provided inside the housing and configured to be insulated from the housing. The power feeding line is configured to include an input-side conductor which is the inner conductor of the input port, an output-side conductor which is the inner conductor of the output port, and an antenna connected to the input-side conductor and the output-side conductor and formed in a spiral shape coaxially with the protrusion portion. The protrusion portion and the antenna form a choke structure.

What is claimed is:

1. A filter circuit, comprising:
a housing formed of a conductor and provided with an input port and an output port that each includes an outer conductor and an inner conductor, the housing being configured to be kept at a ground potential together with the outer conductors of the input port and the output port;
a protrusion portion formed of a conductor, connected to the housing, and configured to protrude in a spiral shape inside the housing; and
a power feeding line provided inside the housing and configured to be insulated from the housing,
wherein the power feeding line is configured to include an input-side conductor which is the inner conductor of the input port, an output-side conductor which is the inner conductor of the output port, and an antenna connected to the input-side conductor and the output-side conductor and formed in a spiral shape coaxially with the protrusion portion, and
wherein the protrusion portion and the antenna form a choke structure.

2. The filter circuit of claim 1, further comprising:
a dielectric provided between the housing and the power feeding line.

3. The filter circuit of claim 1, wherein the input port and the output port have a coaxial structure.

4. The filter circuit of claim 1, wherein the choke structure includes a plurality of fins, and
wherein the plurality of fins includes a first fin connected to a base of the protrusion portion and a second fin connected to a base of the antenna, which are arranged in an alternate manner.

5. The filter circuit of claim 4, wherein the first fin and the second fin of the plurality of fins are formed in a spiral shape.

6. The filter circuit of claim 1, wherein a space between the housing and the protrusion portion and the antenna, which extends from an outer circumferential surface of a base of the antenna to a central surface of the base, forms the choke structure based on a quarter wavelength of an electromagnetic wave to be cut off.

7. The filter circuit of claim 1, wherein the protrusion portion and the antenna are configured to adjust a number of turns of the spiral based on a wavelength of an electromagnetic wave to be cut off.

8. The filter circuit of claim 7, wherein the number of turns of one of the protrusion portion and the antenna is adjusted so that the number of turns of the protrusion portion and the number of turns of the antenna are different from each other.

9. The filter circuit of claim 1, further comprising:
a drive mechanism configured to adjust a distance between a base of the protrusion portion and a base of the antenna.

10. A plasma processing apparatus, comprising:
a processing container;
an electrode provided inside the processing container, wherein two or more frequencies are applied to the electrode; and
a filter circuit,
wherein the filter circuit includes:
a housing formed of a conductor and provided with an input port and an output port that each includes an outer conductor and an inner conductor, the housing being configured to be kept at a ground potential together with the outer conductors of the input port and the output port;
a protrusion portion formed of a conductor, connected to the housing, and configured to protrude in a spiral shape inside the housing; and
a power feeding line provided inside the housing and configured to be insulated from the housing,
wherein the power feeding line is configured to include an input-side conductor which is the inner conductor of the input port, an output-side conductor which is the inner conductor of the output port, and an antenna connected to the input-side conductor and the output-side conductor and formed in a spiral shape coaxially with the protrusion portion, and
wherein the protrusion portion and the antenna form a choke structure.
